(19) United States
(12) Patent Application Publication
(10) Pub. No.: US 2004/0023471 A1
(43) Pub. Date: Feb. 5, 2004

(54) Thermal production of nanowires

(76) Inventors: Kofi Wi Adu, State College, PA (US); Bhabendra K. Pradhan, State College, PA (US); Peter C. Eklund, Boalsburg, PA (US)

Correspondence Address: MCDERMOTT, WILL & EMERY, 600 13th Street, N.W., Washington, DC, 20005-3096, US

(21) Appl. No.: 10/393,348

(22) Filed: Mar. 21, 2003

Related U.S. Application Data
(60) Provisional application No. 60/367,433, filed on Mar. 22, 2002.

(51) Int. Cl. H01L 21/20

(52) U.S. Cl. 438/478

(57) ABSTRACT

Nanowires are fabricated from a solid composition, i.e., a pellet, which includes a semiconductor material together with a metallic additive. The pellet is heated in a quartz or ceramic tube in an over pressure of flowing inert gas. Semiconductor and metal evaporate with the inert gas stream so that micron long crystalline wires collect downstream of the composition. The diameter of these wires is in the range of 2-100 nm.

### FILED OF THE INVENTION

The present invention relates to nanowires and processes for their production and more particularly to a process for obtaining semiconductive nanowires that have utility in the electronic industry.

### BACKGROUND

As is known in the art, a nanowire refers to a wire having a diameter typically in the range of about one nanometer (nm) to about 100 nm. Nanowires are typically fabricated from a metal or a semiconductor material. When wires fabricated from metal or semiconductor materials are provided in approximately 10 nanometers or less size range, some of the electronic and optical properties differ than if the same materials were made in larger sizes.

One-dimensional nanostructures such as nanowires play key roles in applications such as photonics, nano/molecular electronics and thermoelectrics due to their optical and electrooptical properties. As such, considerable efforts have been directed to the synthesis, characterization and application of crystalline nanowire materials. Conventional methods used for the synthesis of nanowires include pulse laser vaporization and chemical vapor deposition.

Intensive efforts have also been directed to the synthesis of compound semiconductors such as gallium arsenide (“GaAs”), a direct-band-gap semiconductor with high electron mobility. Gallium arsenide has been widely used for the fabrication of laser diodes, full-color flat-panel displays and high-speed transistors.

Over the past several years, there has been an increase in demand for nano/molecular electronic devices with high performance and functionality. One technique for fabricating nanowires involves oxide assisted growth This technique requires the use of an oxide of the particular metal or alloy that is to be grown into a wire as well as a laser to oblate the oxide. See, e.g., Shi et al. “Oxide Assisted Growth and Optical Characterization of Gallium-Arsenide Nanowires” 78, Applied Physics Letters, 3304 (2001) and U.S. Pat. No. 6,313,015. However, a continuing need exits for additional methods of fabricating nanowires.

### BRIEF SUMMARY

An advantage of the present invention is a facile method of fabricating nano-sized wires.

The advantages are achieved in part by a very simple thermal process of forming a nanowire. The process comprises heating a pellet, which contains a semiconductor as well as a metallic additive. The semiconductor material can comprise any of those materials typically used in the semiconductor industry as, for example, silicon, gallium, zinc, indium, lead, etc. The present invention is applicable to using starting semiconductor materials that are substantially free of oxides. By substantially free of oxides, it is meant that the semiconductor material does not contain oxides in an amount that is typically larger than found in these materials as impurities, e.g., about 10-100 parts per million. The metallic additive acts, in effect, as a catalyst and solvent and is added in an amount typically between 0.1% to about 10%.

The present invention contemplates using metallic additives such as gold, silver, copper, cobalt, iron, etc. The pellet can be placed in a chamber where a carrier gas can be introduced. The chamber can be maintained at a temperature sufficient to vaporize at least part of the pellet when the carrier gas flows around the pellet. By this process, it is believed that a vapor-liquid-solid growth mechanism causes pure nanowires to be formed downstream of the pellet. Typically the chamber is heated and maintained at a partial pressure of flowing inert carrier gas.

Embodiments include heating the chamber from about 500° C. to about 1200° C. and maintaining the chamber at a pressure from about 10 Torr to about 900 Torr. By this process, it is expected that nanowires can be formed to have a diameter of approximately 2 nm to about 100 nm and a length of approximately 0.05 micron to about 100 microns.

Additional advantages of the present invention will become readily apparent to those having ordinary skill in the art from the following detailed description, wherein the embodiments of the invention are described, simply by way of illustration of the best mode contemplated for carrying out the invention. As will be realized, the invention is capable of other and different embodiments, and its several details are capable of modifications in various obvious respects, all without departing from the invention. Accordingly, the drawings and description are to be regarded as illustrative in nature, and not as restrictive.

### BRIEF DESCRIPTION OF THE DRAWINGS

The various features and advantages of the present invention will become more apparent and facilitated by reference to the accompanying drawings, submitted for purposes of illustration and not to limit the scope of the invention, where the same numerals represent like structure and wherein:

FIG. 1 illustrates an apparatus used for carrying out one aspect of the present invention.

FIG. 2 is a schematic drawing representing a proposed growth mechanism for a gallium arsenide nanowire.

FIG. 3 is a low resolution transmission electron micrograph image of gallium arsenide nanowires made according to one aspect of the present invention.

### DESCRIPTION OF THE INVENTION

The present invention utilizes a thermal evaporation (“thermal batch”) process to synthesize crystalline nanophase materials such as nanowires. Advantageously, the present invention can avoid the use of a laser for pellet vaporization or the need for using an oxide of the semiconductor material prior to formation of the nanowire.

As a general example, a nanowire can be formed by employing a reactor, such as a quartz or ceramic tube, which can be mounted inside a high-temperature (approximately 500-1200° C.) tube furnace. Next, a pellet comprised of a semiconductor material and a metallic additive can be placed inside the quartz tube. A carrier gas, such as an inert gas, can be introduced into the reactor and kept flowing through the reactor at a pressure of approximately 10-900 Torr, e.g., about 100-900 Torr for a time sufficient to facilitate the thermal evaporation of at least a portion of the semiconductor material and the metal additive in the pellet. The carrier gas can be provided at a flow rate of about 10 seem to about 1000 seem. Nanowire products are then formed and collected downstream at the cooler end of the furnace.

A variety of nanophase materials can be synthesized in accordance with the present invention by simply employing different semiconductor materials and metal additives and modifying the temperature of the furnace and the carrier gas flow. Any compound semiconductor capable of generating a high vapor pressure relative to the metallic additive may be used. Examples of such semiconductors include gallium, zinc, indium and lead compositions and alloys.

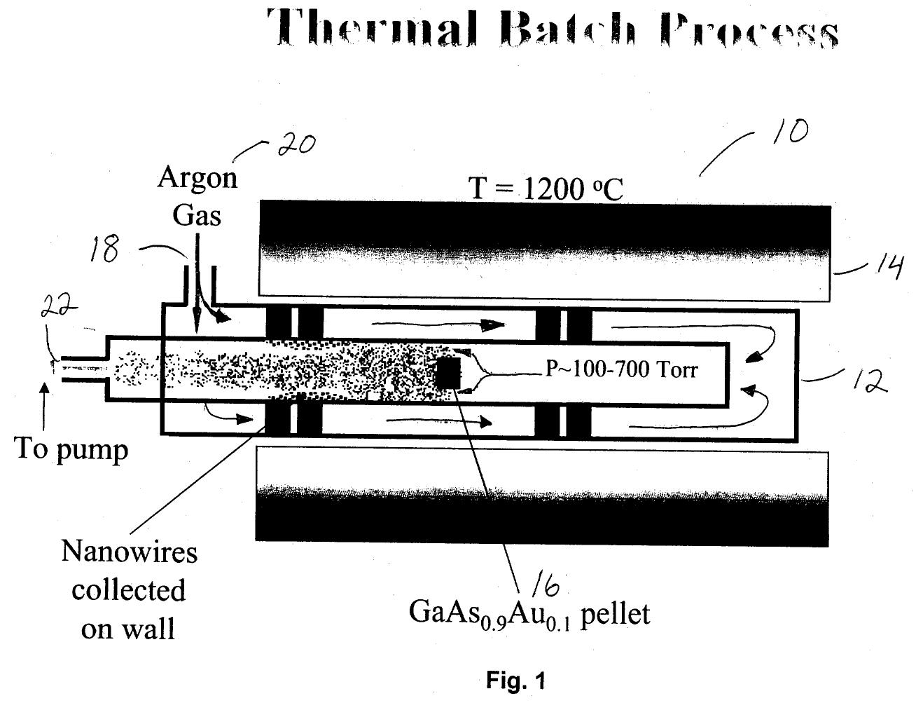

By way of example, FIG. 1 illustrates an apparatus that can be used in practicing the methods of the present invention. As illustrated therein, FIG. 1 shows chamber 12, in this case, a quartz tube mounted inside furnace 14. Chamber 12 contains therein a pellet at one end of the chamber and includes inlet pore 18 for introducing carrier gas 20 and outlet port 22.

In practicing one aspect of the present invention, the pellet contains a combination of a semiconductor material and a metallic catalyst. The semiconductor material can be any of those materials typically used in the semiconductor industry, such as silicon alloys, gallium alloys, zinc alloys, indium alloys or lead alloys. In particular, the semiconductor material can comprise gallium arsenide, gallium phosphide, zinc sulfide, indium phosphide, or lead telluride. The metallic additive can be gold, silver, copper, cobalt, or iron.

In one embodiment of the present invention, the gallium arsenide is used as the semiconductor material and gold is used as the metallic additive. These can be mixed at various ratios where the semiconductor material is in the larger amount as, for example, in a ratio of approximately 5:1 to approximately 1000:1 of the semiconductor material to the metallic additive. The semiconductor material is typically substantially free of oxides, e.g., less than about 0.5 weight % (wt. %) oxides, or even less than about 0.1 wt. % oxides.

In operation, furnace 14 heats chamber 12 during introduction of carrier gas 20 which is introduced at port 18 and heated by the walls of chamber 12 when flowing over and around pellet 16 and exiting at port 22. Although not shown, a vacuum pump can be attached to port 22 as well as a valve to maintain the chamber at a partial pressure, such as from about 100 Torr to about 900 Torr. During operation, nanowires are deposited from pellet 16 at a point downstream of the pellet. These nanowires collect along the cooler parts of the chamber and can be removed in relatively pure form after the apparatus cools.

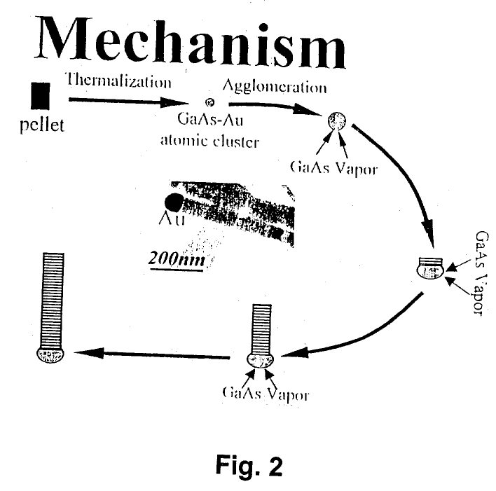

It is believed that the nanowires are produced from the pellets in relatively pure form by a process involving vapor-liquid-solid deposition and growth. The proposed mechanism, discussed for illustration purposes and not intended to limit the present invention, is shown in FIG. 2. As shown therein, it is believed that pellet 16 thermalizes to an agglomeration of the semiconductor material and metallic additive. In this example, gallium arsenide and gold are shown for illustration and not by way of limitation. Continued heating causes vaporization, semiconductor material together with the metallic additive. A pseudo binary eutectic GaAs:Au nanoparticle forms and remains liquid during nanowire growth. The nanowire forms as a precipitate at the surface of the nanowire. GaAs vapors deposit on the eutectic liquid nanoparticle and fuel the grown of the nanowire from the surface. This is the vapor-liquid solid growth mechanism. It is believed that the eutectic nanoparticle in part, determines the diameter of the nanowire. By this process it is expected that nanowires having dimensions of about 2 nm to about 100 nm in diameter and in a length of approximately 0.05 micron to about 100 micron or longer can be produced.

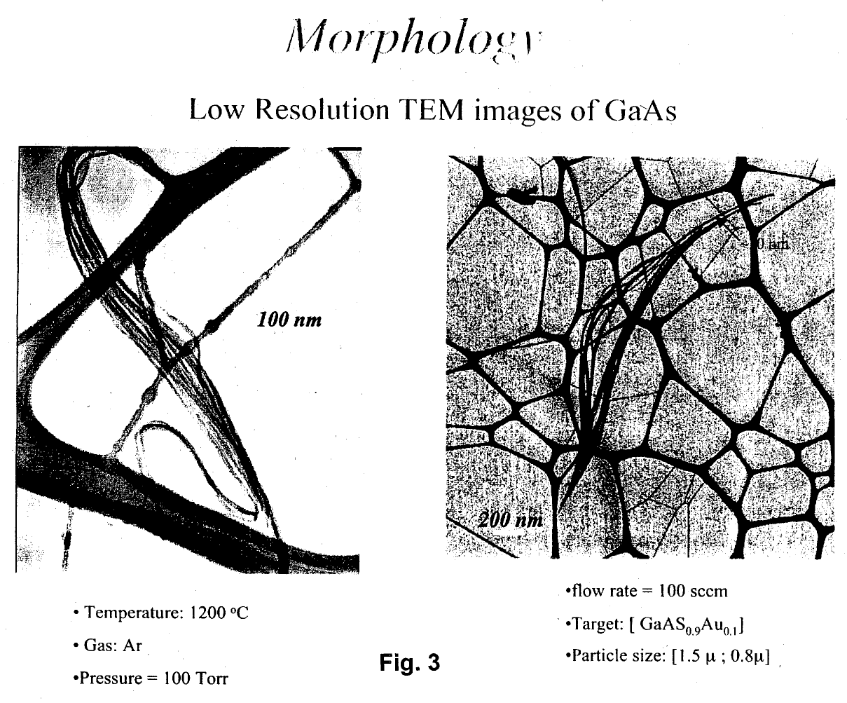

As an example of practicing the present invention, wire-like nano structures of gallium arsenide were produced in an apparatus as shown in FIG. 1 by heating the furnace to about 1200° C. Argon, as an inert carrier gas, was introduced at a flow rate of about 100 sccm. The reaction chamber was maintained at a pressure of about 100 Torr. The pellet comprised gallium arsenide and gold having particle sizes ranging from 1.5 microns to about 0.8 microns. FIG. 3 shows a low resolution transmission electron micrograph of the gallium arsenide nanowires produced by this process.

In the preceding detailed description, the present invention is described with reference to specifically exemplary embodiments thereof. It will, however, be evident that various modifications and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A method of forming a nanowire, the method comprising:
heating a pellet, which contains a semiconductor material substantially free of oxides and a metallic additive, in a chamber;
providing a carrier gas to the chamber to flow over or around the pellet at a sufficient rate to cause formation of a nanowire in the chamber.

2. The method of claim 1, comprising heating the chamber from about 500° C. to about 1200° C.

3. The method of claim 1, comprising maintaining the chamber at a pressure from about 100 Torr to about 900 Torr.

4. The method of claim 1, comprising providing the carrier gas to the chamber at a flow rate of about 10-1000 sccm.

5. The method of claim 1, wherein the semiconductor material comprises gallium arsenide, gallium phosphide, zinc sulfide, indium phosphide, or lead telluride.

6. The method of claim 1, wherein the metallic additive comprises gold, silver, copper, cobalt, or iron.

7. The method of claim 1, wherein the semiconductor material has no more than 0.5 wt. % of oxides.

8. The method of claim 1, comprising heating a pellet containing gallium arsenide as the semiconductor material and gold as the metallic additive.

9. The method of claim 8, wherein the gallium arsenide and the gold comprise the pellet in a ratio of approximately 5:1 to approximately 1000:1.

10. The method of claim 9, comprising and heating the chamber from about 500° C. to about 1200° C., providing a carrier gas including argon, and maintaining the chamber at a pressure from about 100 Torr to about 900 Torr.

11. Nanowires made form the method of claim 1, wherein the nanowires have a diameter of approximately 2 nm to 100 nm and a length of approximately 0.05 microns to 100 microns.
